(19) United States
(12) Patent Application Publication
(10) Pub. No.: US 2024/0421128 A1
(43) Pub. Date: Dec. 19, 2024

(54) SEMICONDUCTOR DEVICE WITH MULTIPLE STACKED PASSIVE DEVICES

(71) Applicant: QUALCOMM Incorporated, San Diego, CA (US)

(72) Inventors: Yangyang SUN, San Diego, CA (US); Yi-Hang LIN, Hsinchu City (TW); Dongming HE, San Diego, CA (US); Lily ZHAO, San Diego, CA (US); Ryan LANE, San Diego, CA (US)

(21) Appl. No.: 18/335,532

(22) Filed: Jun. 15, 2023

(51) Int. Cl. H01L 25/065; H01L 21/56; H01L 23/00; H01L 23/31; H01L 23/48; H01L 23/498; H01L 27/02

(52) U.S. Cl. CPC H01L 25/0657; H01L 21/565; H01L 23/3128; H01L 23/481; H01L 23/49822; H01L 24/08; H01L 27/0248; H01L 28/60; H01L 2224/08145; H01L 2225/06541; H01L 2924/19041; H01L 2924/30205

(57) ABSTRACT

Disclosed is a semiconductor device. In an aspect, a semiconductor device includes: a first-tier passive device including a substrate portion, a passive device portion, and a metallization portion disposed in a stacked configuration; and one or more second-tier passive devices disposed over the first-tier passive device. Each one of the one or more second-tier passive devices includes: a substrate portion, a passive device portion, and a metallization portion disposed in a stacked configuration; and a set of through substrate vias (TSVs) passing through a corresponding substrate portion and electrically coupled to a corresponding metallization portion. The semiconductor device comprises a passive component including the passive device portion of the first-tier passive device electrically coupled to one or more passive device portions of the one or more second-tier passive devices through the metallization portions of the first-tier passive device and the one or more second-tier passive devices.

### TECHNICAL FIELD

The present disclosure generally relates to a semiconductor device, and more particularly, to a semiconductor device with multiple stacked passive devices.

### BACKGROUND

Integrated circuit (IC) technology has achieved great strides in advancing computing power through miniaturization of electrical components. An IC device may be implemented in the form of an IC chip that has a set of circuits integrated thereon, including a plurality of active components (e.g., transistors) and passive components (e.g., diodes, capacitors, inductors, and/or resistors) and layers of contacts and interconnects above the active and passive components. In some implementations, one or more IC chips can be physically carried and protected by an IC package based on a packaging substrate.

In some implementations, embedded passive devices, such as deep trench capacitors, have been incorporated in IC packaging for performance improvement and package size reduction. One factor driving the use of such embedded passive devices is the desire to obtain small form factor products with equivalent or better electrical performance than their larger passive device counterparts. In some implementations, depending on the size and/or thickness of the packaging substrate and the process for embedding a passive device in a packaging substrate, the size of the passive device may need to match the thickness of a core of the packaging substrate, and the electrical characteristic of the passive device may be limited. In some implementations, the passive device to be embedded in the packaging substrate may not include an electrostatic discharge (ESD) protection circuit provided therein.

Accordingly, there is a need for a semiconductor device (that can be embedded in a packaging substrate as an embedded passive device) and a method of making the semiconductor device.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor device includes a first-tier passive device including a substrate portion, a passive device portion, and a metallization portion disposed in a stacked configuration, the passive device portion being disposed between the substrate portion and the metallization portion; one or more second-tier passive devices disposed over the first-tier passive device, each one of the one or more second-tier passive devices including: a substrate portion, a passive device portion, and a metallization portion disposed in a stacked configuration, the passive device portion being disposed between the substrate portion and the metallization portion; and a set of through substrate vias (TSVs) passing through a corresponding substrate portion and electrically coupled to a corresponding metallization portion; and a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

In an aspect, a method of manufacturing semiconductor device includes providing a first-tier passive device, wherein the first-tier passive device includes a substrate portion, a passive device portion, and a metallization portion disposed in a stacked configuration, the passive device portion being between disposed the substrate portion and the metallization portion; stacking one or more second-tier passive devices over the first-tier passive device to form the semiconductor device, wherein each one of the one or more second-tier passive devices includes: a substrate portion, a passive device portion, and a metallization portion disposed in a stacked configuration, the passive device portion being disposed between the substrate portion and the metallization portion; and a set of through substrate vias (TSVs) passing through a corresponding substrate portion and electrically coupled to a corresponding metallization portion; and forming a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

In an aspect, an electronic device includes an integrated circuit device including a semiconductor device, and the semiconductor device comprising: a first-tier passive device including a substrate portion, a passive device portion, and a metallization portion disposed in a stacked configuration, the passive device portion being disposed between the substrate portion and the metallization portion; one or more second-tier passive devices disposed over the first-tier passive device, each one of the one or more second-tier passive devices including: a substrate portion, a passive device portion, and a metallization portion disposed in a stacked configuration, the passive device portion being disposed between the substrate portion and the metallization portion; and a set of through substrate vias (TSVs) passing through a corresponding substrate portion and electrically coupled to a corresponding metallization portion; and a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 is a cross-sectional view of an example packaging substrate with a semiconductor device embedded therein, according to aspects of the disclosure.

FIG. 2 is a cross-sectional view of an example deep trench capacitor (DTC), according to aspects of the disclosure.

FIG. 3 is a cross-sectional view of an example semiconductor device that is configured without multiple stacked passive devices, according to aspects of the disclosure.

FIG. 4 is a cross-sectional view of a first example semiconductor device that is configured with multiple stacked passive devices, according to aspects of the disclosure.

FIGS. 5A-5F illustrate structures at various stages of manufacturing a semiconductor device of FIG. 4, according to aspects of the disclosure.

FIG. 6 is a cross-sectional view of a second example semiconductor device that is configured with multiple stacked passive devices, according to aspects of the disclosure.

FIGS. 7A-7G illustrate structures at various stages of manufacturing a semiconductor device of FIG. 6, according to aspects of the disclosure.

FIG. 8 illustrates a method for manufacturing a semiconductor device, according to aspects of the disclosure.

FIG. 9 illustrates a profile view of a package that includes a surface mount substrate and an integrated device, according to aspects of the disclosure.

FIG. 10 illustrates an exemplary flow diagram of method for fabricating a package that includes a substrate, an integrated device and an integrated passive device.

FIG. 11 illustrates various electronic devices that may integrate an electronic component, an electronic circuit, an integrated device, an integrated passive device, a passive component, a package, and/or a device package described herein.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to a semiconductor device with multiple stacked passive devices and a manufacturing method of making the semiconductor device. Some aspects more specifically relate to a semiconductor device based on a first-tier passive device and one or more second-tier passive devices stacked on the first-tier passive device.

Particular aspects of the subject matter described in this disclosure can be implemented to realize one or more of the following potential advantages. In some examples, by forming a semiconductor device with multiple stacked passive devices, the thickness of the semiconductor device may be adjustable to match the thickness of the core for a particular packaging task. The first-tier passive device of the semiconductor device may further include an ESD protection circuit. Also, an electrical characteristic of a resulting passive component may be improved or enhanced based on a combined effect of the stacked passive devices.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

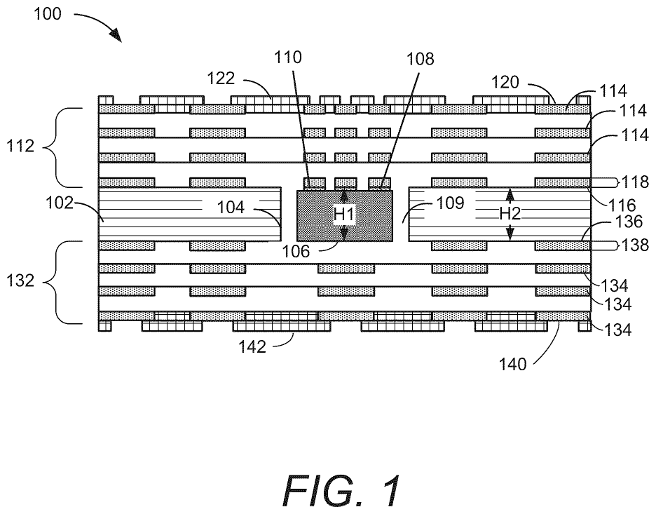

FIG. 1 is a cross-sectional view of an example packaging substrate 100 with a semiconductor device 106 embedded therein, according to aspects of the disclosure. In this example, the packaging substrate 100 includes a core 102 having a cavity 104 that extends entirely through the core 102. The semiconductor device 106 is disposed within the cavity 104. The semiconductor device 106 has an upper surface 108 with metal terminals 110 that provide an electrical connection to a passive component (e.g., a capacitor) configured in the semiconductor device 106.

The packaging substrate 100 further includes a plurality of dielectric layers 112 and corresponding patterned metallization layers 114 overlying an upper surface 116 of the core 102. A patterned metallization layer 118 is disposed at the upper surface 116 of the core 102 to provide an electrical connection between the metal terminals 110 of the semiconductor device 106 and the patterned metallization layers 114. In an aspect, the same dielectric resin material as used in forming the plurality of dielectric layers 112 may be used in the interstitial regions 109 of the cavity 104 between the sidewalls of the semiconductor device 106 and the sidewalls of the cavity 104. Dispensing a dielectric resin over the semiconductor device 106 and in the interstitial regions 109 assists in securing the semiconductor device 106 within the cavity 104 so that the metal terminals 110 remain in electrical contact with corresponding portions of the patterned metallization layer 118 once the dielectric resin is cured.

In an aspect, an uppermost patterned metallization layer 114 at an upper surface 120 of the packaging substrate 100 is connected to a plurality of metal terminals 122. The patterned metallization layers 114 provide a conductive path between the metal terminals 110 of the semiconductor device 106 and the metal terminals 122. In an aspect, the plurality of metal terminals 122 may be configured for connection to an electronic package of a surface-mounted device (not shown in FIG. 1).

In an aspect, a further plurality of dielectric layers 132 and corresponding patterned metallization layers 134 overlie a lower surface 136 of the core 102. Here, a patterned metallization layer 138 is disposed over the lower surface 136 of the core 102. A lowermost patterned metallization layer 134 at a lower surface 140 of the packaging substrate 100 is connected to a plurality of metal terminals 142. The patterned metallization layers 134 provide a conductive path to the metal terminals 142. In an aspect, the plurality of metal terminals 142 may be configured for connection to an electronic package of a further surface mounted device (not shown in FIG. 1) or to a circuit board for connection with other devices.

In FIG. 1, the semiconductor device 106 has a height H1 that is substantially the same as the thickness H2 of the core 102. During manufacture of the packaging substrate 100, the semiconductor device 106 is inserted in the cavity 104 before a dielectric resin is injected to fill the interstitial regions 109 between the cavity 104 and semiconductor device 106. During insertion, the semiconductor device 106 is carefully aligned within the cavity 104 to ensure that the metal terminals 110 properly contact and electrically bond with the corresponding portions of the patterned metallization layer 118. Additionally, the injection of the dielectric resin in the interstitial regions 109 should be undertaken with care so as not to disturb the initial alignment of the semiconductor device 106. In an aspect, the dielectric resin, once cured, secures the semiconductor device 106 at its proper location within the cavity 104.

In scenarios in which the height H1 of the semiconductor device 106 and thickness H2 of the core 102 are substantially the same, the insertion of the semiconductor device 106 in the cavity 104 and subsequent injection and cure of the dielectric resin may be implemented using the processing technology as described with reference to FIG. 1.

In some aspects, the thickness H2 of the core 102 may be equal to or less than about 760 micrometers. In some aspects, a recent trend is to have a thicker core in order to address issues such as substrate warpage control, where the thickness H2 of the core 102 may be greater than about 760 micrometers (μm), or even ranges from 1.2 millimeters (mm) to 1.8 mm.

However, according to some current designs, the height H1 of the semiconductor device 106 that consists of a single passive device may range from 20 μm to 780 μm. In some aspects, according to the present application, a semiconductor device with multiple stacked passive devices may have a height adjustable to match the thickness of the core for a particular packaging task.

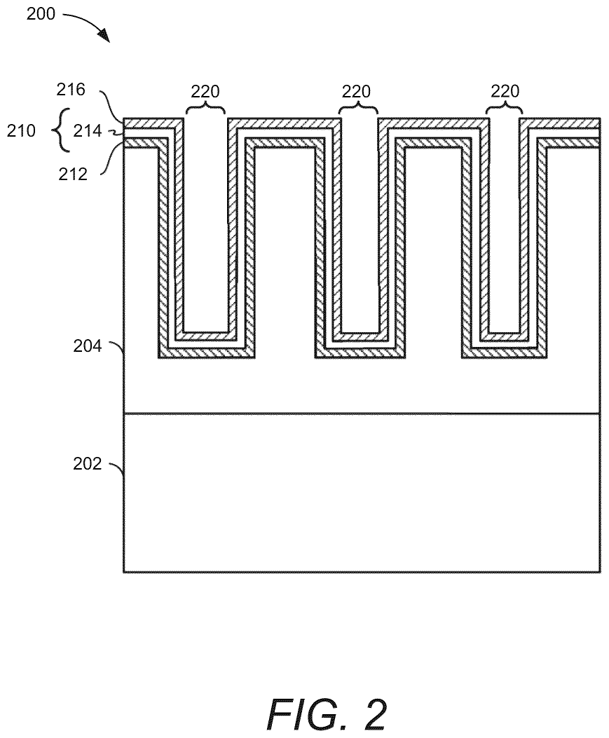

In some aspects, a passive device described in this disclosure may be a capacitor, an inductor, a resistor, or a combination thereof. FIG. 2 is a cross-sectional view of an example deep trench capacitor 200, according to aspects of the disclosure. In some aspects, a passive device usable in the packaging substrate 100 in FIG. 1 may be a capacitor configured based on the deep trench capacitor 200.

In FIG. 2, a deep trench capacitive structure 210 is disposed in trenches 220 of an insulator 204 on a substrate 202. The deep trench capacitive structure 210 may include a conductive layer 212, a dielectric layer 214, and a conductive layer 216. The dielectric layer 214 separates the conductive layer 212 from the conductive layer 216. The conductive layers 212 and 216 of the deep trench capacitive structure 210 form electrodes of the capacitor 200 and may be connected to terminals at, for example, a surface of a resulting passive device (e.g., the upper surface 108 with metal terminals 110 of semiconductor device 106 shown in FIG. 1). In some scenarios, multiple capacitive structures may be formed from an array of deep trenches in a substrate and filled with an electrical insulator (e.g., a dielectric) between layers of electrodes.

In some aspects, the conductive layer 212 and/or the conductive layer 216 may include copper, tungsten, aluminum, or a combination thereof. In some aspects, the conductive layer 212 and/or the conductive layer 216 may include polysilicon, doped silicon, or a combination thereof. In some aspects, the dielectric layer 214 may include silicon oxide, a high-k material (having a relative dielectric constant (k) greater than that of the silicon dioxide), or a combination thereof.

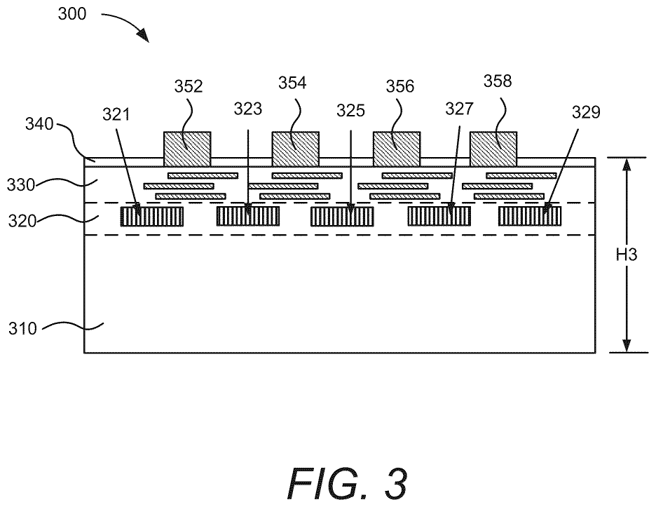

FIG. 3 is a cross-sectional view of an example semiconductor device 300 that is configured without multiple stacked passive devices, according to aspects of the disclosure. In some aspects, the semiconductor device 300 may be usable as the semiconductor device 106 illustrated in FIG. 1. The semiconductor device 300 includes a substrate portion 310, a passive device portion 320, and a metallization portion 330 disposed in a stacked configuration, with the passive device portion 320 being disposed between the substrate portion 310 and the metallization portion 330. In some aspects, the metallization portion 330 may be manufactured based on a back end of line (BEOL) process. In some aspects, the passive device portion 320 may be manufactured based on a front end of line (FEOL) process or a middle of line (MOL) process.

The semiconductor device 300 includes a passivation layer 340 over the metallization portion 330. The semiconductor device 300 further includes electrical terminal structures 352, 354, 356, and 358, which may correspond to the metal terminals 110 illustrated in FIG. 1. In some aspects, the electrical terminal structures 352, 354, 356, and 358 may include a copper pillar, a conductive pad, solder, or a combination thereof.

In some aspects, the substrate portion 310 may include silicon, germanium, and/or gallium arsenide. In some aspects, the substrate portion 310 may correspond to the substrate 202 illustrated in FIG. 2. In some aspects, the passivation layer 340 may include an oxide material (e.g., silicon dioxide) or a nitride material (e.g., silicon nitride).

In some aspects, the passive device portion 320 includes deep trench capacitive structures 321, 323, 325, 327, and 329, and each deep trench capacitive structure of the deep trench capacitive structures may have a configuration corresponding to the deep trench capacitive structure 210 illustrated in FIG. 2. In some aspects, the metallization portion 330 may include interlayer dielectric layers and conductive layers (not labeled). In some aspects, the metallization portion 330 may electrically coupling the deep trench capacitive structures 321, 323, 325, 327, and 329 in series or parallel and to the electrical terminal structures 352, 354, 356, and 358 in order to form one or more passive components. In some aspects, the deep trench capacitive structures 321, 323, 325, 327, and 329 may be configured as one capacitor, and the electrical terminal structures 352, 354, 356, and 358 may be divided into two subsets as separate electrical terminals of the resulting capacitor. In some aspects, the deep trench capacitive structures 321, 323, 325, 327, and 329 may be configured as two capacitors, where two of the electrical terminal structures 352, 354, 356, and 358 may be configured as the electrical terminals of a first resulting capacitor and the other two of the electrical terminal structures 352, 354, 356, and 358 may be configured as the electrical terminals of a second resulting capacitor.

In some aspects, the height H3 of the semiconductor device 300 that consists of a single passive device may range from 20 μm to 780 μm. In some aspects, when a thickness of the core of a packaging substrate is much greater than 780 μm, the semiconductor device 300 may not be embedded in such packaging substrate based on the packaging scheme illustrated in FIG. 1 (e.g., being inserted into a through cavity of a core).

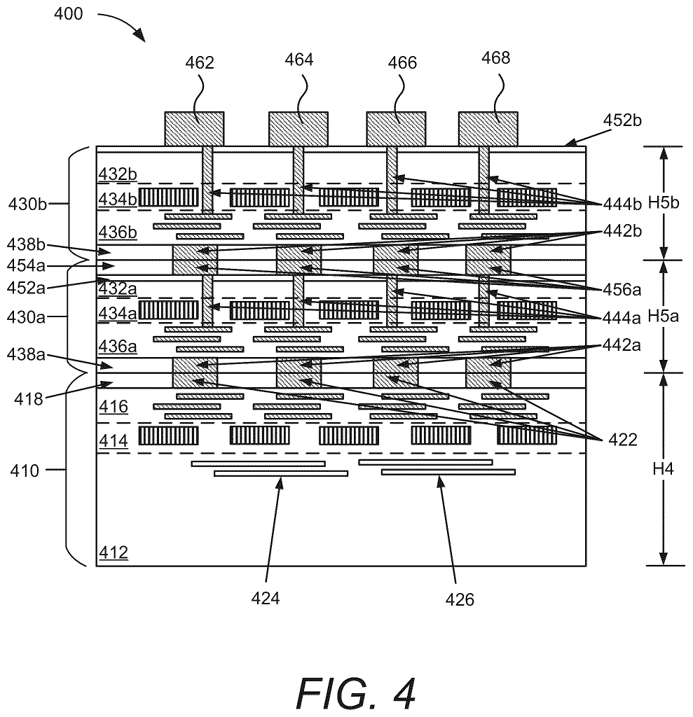

FIG. 4 is a cross-sectional view of a first example semiconductor device 400 that is configured with multiple stacked passive devices, according to aspects of the disclosure. In some aspects, the semiconductor device 400 may be referred to as a hybrid bond multi-stacking semiconductor device. In some aspects, the semiconductor device 400 may be usable as the semiconductor device 106 in FIG. 1.

The semiconductor device 400 includes a first-tier passive device 410 and one or more second-tier passive devices 430a and 430b disposed over the first-tier passive device 410. While the example depicted in FIG. 4 shows two second-tier passive devices 430a and 430b over the first-tier passive device 410, in some aspects, there may be only one second-tier passive device or more than two second-tier passive devices stacked over the first-tier passive device 410.

The first-tier passive device 410 includes a substrate portion 412, a passive device portion 414, and a metallization portion 416 disposed in a stacked configuration. In some aspects, the passive device portion 414 may be disposed between the substrate portion 412 and the metallization portion 416. In this example, the passive device portion 414 of the first-tier passive device 410 is disposed over the substrate portion 412 of the first-tier passive device 410. The first-tier passive device 410 further includes a passivation layer 418 and electrical terminal structures 422 over the metallization portion 416. In some aspects, the substrate portion 412, the passive device portion 414, the metallization portion 416, the passivation layer 418, and the electrical terminal structures 422 may correspond to the substrate portion 310, the passive device portion 320, the metallization portion 330, the passivation layer 340, and the electrical terminal structures 352-358 in FIG. 3, and detailed description thereof may be omitted.

In some aspects, while the deep trench capacitive structures are illustrated in this disclosure as the passive elements disposed in the passive device portion, the passive device portion may include a deep trench capacitor, an integrated stack capacitor, a metal-insulator-metal capacitor, a metal-oxide-metal capacitor, or a combination thereof. In some aspects, the passive device portion may include a capacitor, an inductor, a resistor, or a combination thereof.

In some aspects, the first-tier passive device 410 may further include one or more electrostatic discharge (ESD) protection circuits 424 and 426 disposed in the substrate portion 412 of the first-tier passive device 410 and electrically coupled to the passive device portion 414 of the first-tier passive device 410. In some aspects, the one or more ESD protection circuits 424 and 426 may include diodes (which are considered as passive components in this disclosure) configured to provide ESD protection functionality for the resulting passive component of the semiconductor device 400.

Moreover, each one of the one or more second-tier passive devices 430a and 430b include a substrate portion 432a/432b, a passive device portion 434a/434b, and a metallization portion 416a/416b disposed in a stacked configuration, with the passive device portion 434a/434b being disposed between the substrate portion 432a/432b and the metallization portion 436a/436b. Each one of the one or more second-tier passive devices 430a and 430b may include a set of through substrate vias (TSVs) 444a/444b passing through the corresponding substrate portion 432a/432b and electrically coupled to the corresponding metallization portion 436a/436b.

In this example, the substrate portion 432a of the second-tier passive device 430a is disposed over the passive device portion 434a of the second-tier passive device 430a, and the substrate portion 432b of the second-tier passive device 430b is disposed over the passive device portion 434b of the second-tier passive device 430b. Also, each one of the one or more second-tier passive devices 430a and 430b may include a passivation layer 438a and electrical terminal structures 442a/442b adjacent the metallization portion 436a/436b. The second-tier passive device 430a may further include an etch stop layer 452a adjacent the substrate portion 432a, and a passivation layer 454a and electrical terminal structures 456a above the etch stop layer 452a. The second-tier passive device 430b may further include an etch stop layer 452b adjacent the substrate portion 432b. Also, the semiconductor device 400 may include electrical terminal structures 462, 464, 466, and 468 above the etch stop layer 452b.

Various portions of the second-tier passive devices 430a and 430b are depicted as an non-limiting example. In some aspects, different portions within each one of the second-tier passive device 430a/430b may be individually configured to be stacked based on the same or a reverse order as illustrated in FIG. 4.

In some aspects, the semiconductor device 400 includes a passive component, which further includes the passive device portion 414 of the first-tier passive device 410 electrically coupled to one or more passive device portions 434a/434b of the one or more second-tier passive devices 430a/430b through the metallization portion 416 of the first-tier passive device 410, one or more sets of TSVs 444a/444b of the one or more second-tier passive devices 430a/430b, and one or more metallization portions 436a/436b of the one or more second-tier passive devices 430a/430b. In some aspects, at least two electrical terminal structures of the electrical terminal structures 462, 464, 466, and 468 disposed on an upper surface of an uppermost second-tier passive device (e.g., the second-tier passive device 430b in this example) of the one or more second-tier passive device 430a/430b may be configured as electrical terminals of the resulting passive component of the semiconductor device 400.

In some aspects, the electrical terminal structures 422 may be first conductive structures in the form of conductive pads, and the electrical terminal structures 442a may be second conductive structures in the form of conductive pads bonded to the first conductive structures. In some aspects, the first conductive structures may be connected to the second conductive structures based on fusion bonding or hybrid bonding. In some aspects, the electrical terminal structures 456a may be third conductive structures in the form of conductive pads, and the electrical terminal structures 442b may be fourth conductive structures in the form of conductive pads bonded to the third conductive structures. In some aspects, the third conductive structures may be connected to the fourth conductive structures based on fusion bonding or hybrid bonding.

In some aspects, the substrate portion 432a of the second-tier passive device 430a is disposed over the passive device portion 434a of the second-tier passive device 430a as shown in FIG. 4. In this scenario, the second conductive structures to be bonded with the first-tier passive device 410 (e.g., the electrical terminal structures 442a) are disposed on a lower surface of the second-tier passive device 430a and are adjacent the metallization portion 436a of the second-tier passive device 430a. In some aspects, the passive device portion 434a of the second-tier passive device 430a may be disposed over the substrate portion 432a of the second-tier passive device 430a (e.g., flipping the second-tier passive device 430a as depicted in FIG. 4 upside down). In this scenario, the second conductive structures to be bonded with the first-tier passive device 410 (e.g., the electrical terminal structures 456a after flipping the second-tier passive device 430a depicted in FIG. 4) may be disposed on a lower surface of the second-tier passive device 430a and are connected to the set of TSVs 444a of the second-tier passive device 430a.

In some aspects, the substrate portion 412 of the first-tier passive device 410 may not have been further trimmed and thus may maintain substantially the thickness of a wafer substrate for manufacturing the first-tier passive device 410. In some aspects, the thickness H4 of the first-tier passive device 410 may be similar to the thickness H3 of the semiconductor device 300 and may range from 20 μm to 780 μm. In some aspects, the substrate portion 432a/432a of the second-tier passive device 430a/430b may have been further trimmed and thus may have a thickness less than the thickness of a wafer substrate for manufacturing the second-tier passive device 430a/430b. As such, a thickness of the substrate portion 412 of the first-tier passive device 410 may be greater than a thickness of substrate portions 432a/432b of the one or more second-tier passive devices 430a/430b. In some aspects, the thickness H4a/H4b of the second-tier passive device 430a/430b may range from 20 μm to 100 μm.

In some aspects, a total thickness of the semiconductor device 400 may be adjusted, based on adjusting the number of second-tier passive devices and the thickness of the second-tier passive device(s), to match the thickness of the core for a particular packaging task. For example, if the first-tier passive device 410 has a thickness H4 of 780 μm, and each of the second-tier passive device 430a/430b has a thickness H5a/H5b of 50 μm, the total thickness of stacking N second-tier passive devices would be (780+50×N) μm. In some aspects, an overall thickness of the semiconductor device 400 may range from 1.2 mm to 1.8 mm.

Moreover, the resulting passive component of the semiconductor device 400 may have an electrical characteristic based on a combined effect of at least the passive device portions 414, 434a, and/or 434b. In one example, the resulting passive component may be a capacitor, and a capacitance of the resulting passive component may be a combination of capacitive elements of the passive device portions 414, 434a, and/or 434b. In another example, the resulting passive component may be an inductor, and an inductance of the resulting passive component may be a combination of inductive elements of the passive device portions 414, 434a, and/or 434b. As such, a greater capacitance or inductance may be implemented within the same footprint as the semiconductor device 300 based on stacking multiple passive devices.

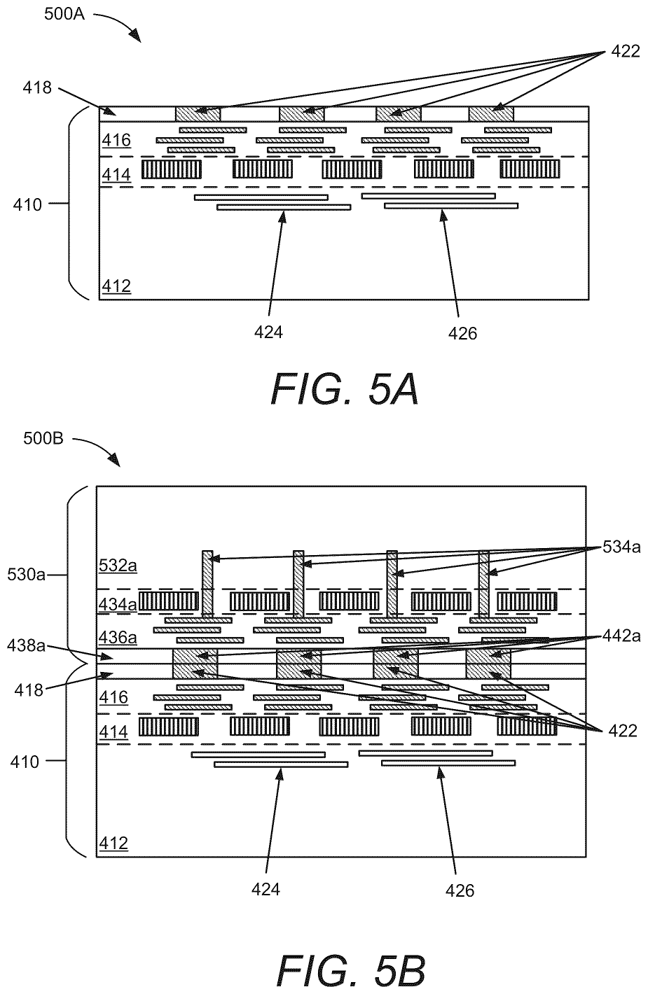

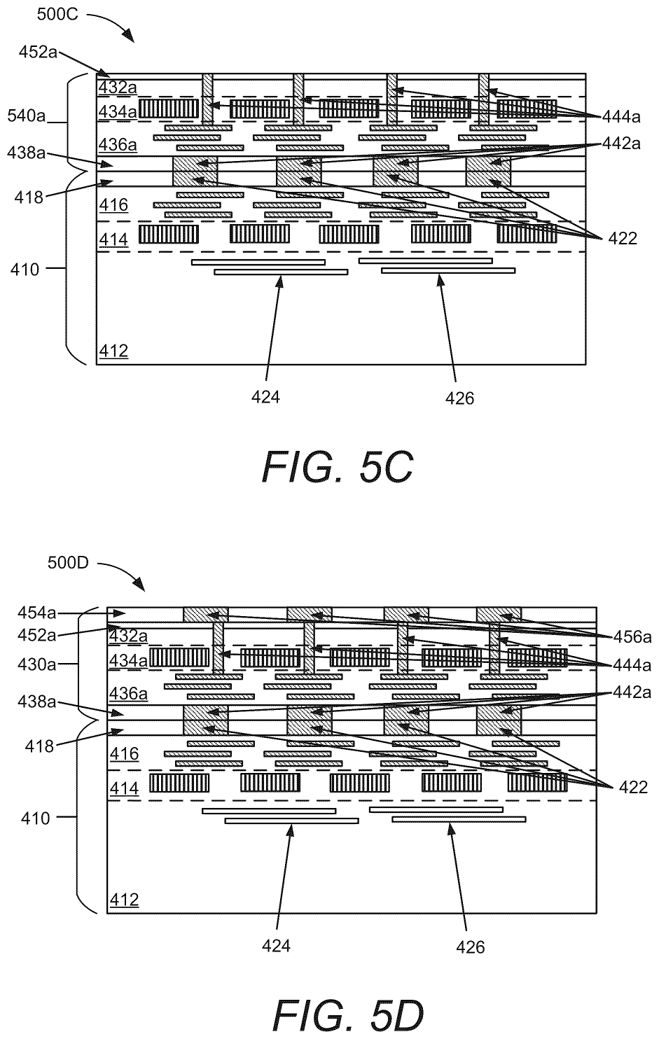

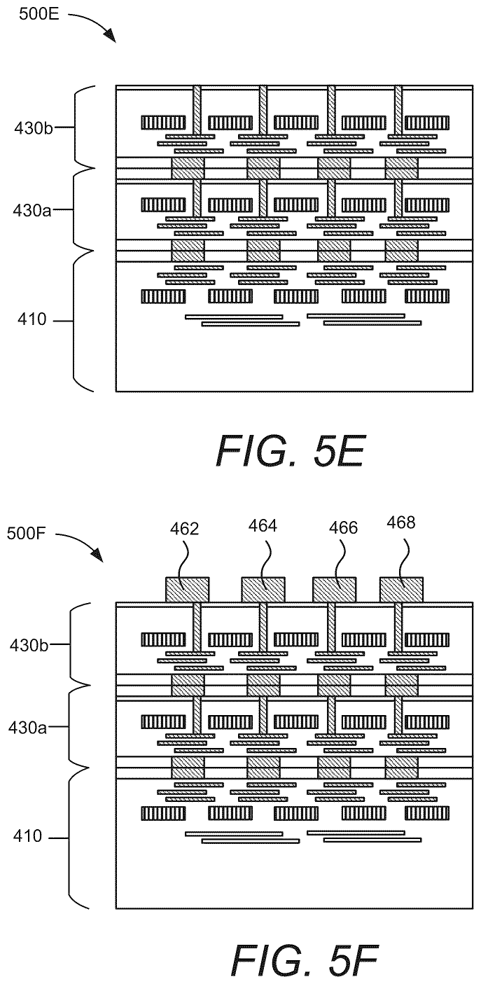

FIGS. 5A-5F illustrate structures at various stages of manufacturing a semiconductor device 400 of FIG. 4, according to aspects of the disclosure. The elements illustrated in FIGS. 5A-5F that are the same or similar to those of the semiconductor device 400 in FIG. 4 are given the same reference numbers, and the detailed description thereof may be omitted.

As shown in FIG. 5A, a structure 500A is provided. The structure 500A includes the first-tier passive device 410. In some aspects, the first-tier passive device 410 includes a substrate portion 412, a passive device portion 414, and a metallization portion 416 disposed in a stacked configuration. The first-tier passive device 410 further includes a passivation layer 418 and electrical terminal structures 422 over the metallization portion 416. In some aspects, the first-tier passive device 410 may further include one or more ESD protection circuits 424 and 426 disposed in the substrate portion 412 of the first-tier passive device 410 and electrically coupled to the passive device portion 414 of the first-tier passive device 410.

In some aspects, the electrical terminal structures 422 may be conductive structures in the form of conductive pads and may include copper. In some aspects, after forming the electrical terminal structures 422 on the metallization portion 416, the passivation layer 418 may be formed by depositing a passivation material (e.g., an oxide material or a nitride material), and the upper surface of the first-tier passive device 410 may be prepared based on a chemical-mechanical polishing (CMP) process followed by a surface cleaning process (e.g., a surface plasma cleaning process).

As shown in FIG. 5B, a structure 500B is formed based on the structure 500A by a second-tier passive device 530a to the first-tier passive device 410. The second-tier passive device 530a may include a substrate portion 532a, a passive device portion 434a, and a metallization portion 436a disposed in a stacked configuration. The second-tier passive device 530a may include a set of TSVs 534a connected to the metallization portion 436a and extending into the substrate portion 532a. The second-tier passive device 530a may further include a passivation layer 438a and electrical terminal structures 442a adjacent the metallization portion 436a.

In some aspects, the second-tier passive device 530a may be manufactured in a manner similar to the first-tier passive device 410 (except the formation of the TSVs in the substrate portion and absence of the ESD protection circuits) and then flipped upside down. The electrical terminal structures 442a may be conductive structures in the form of conductive pads, and the electrical terminal structures 422 and the electrical terminal structures 442a may be bonded by performing a fusion bonding process or a hybrid bonding process. In some aspects, the electrical terminal structures 422 and the electrical terminal structures 442a may be bonded by other bonding processes such as based on soldering bonding.

As shown in FIG. 5C, a structure 500C is formed based on the structure 500B by forming the second-tier passive device 540a based on the second-tier passive device 530a. In some aspects, a portion of the substrate portion 532a of the second-tier passive device 530a may be recessed (e.g., based on a CMP process) to become the trimmed substrate portion 432a. A layer of etch stop material (e.g., silicon nitride) may be deposited on the substrate portion 432a (e.g., based on a chemical vapor deposition (CVD) process), followed by a polishing process (e.g., based on a CMP process) to reduce the thickness of the layer of etch stop material to become the etch stop layer 452a, with the set of TSV 534a trimmed and revealed and becoming a set of TSV 444a.

As shown in FIG. 5D, a structure 500D is formed based on the structure 500C by forming the second-tier passive device 430a based on the second-tier passive device 540a. In some aspects, a passivation layer 454a and electrical terminal structures 456a may be formed above the etch stop layer 452a.

As shown in FIG. 5E, a structure 500E is formed based on the structure 500D by stacking another second-tier passive device 430b on the second-tier passive device 430a, based on the operations similar to those illustrated with reference to FIGS. 5B and 5C.

As shown in FIG. 5F, a structure 500F is formed based on the structure 500E by forming the electrical terminal structures 462, 464, 466, and 468 on the upper surface of the uppermost second-tier passive device 430b. In some aspects, the electrical terminal structures 462, 464, 466, and 468 may include a copper pillar, a conductive pad, solder, or a combination thereof.

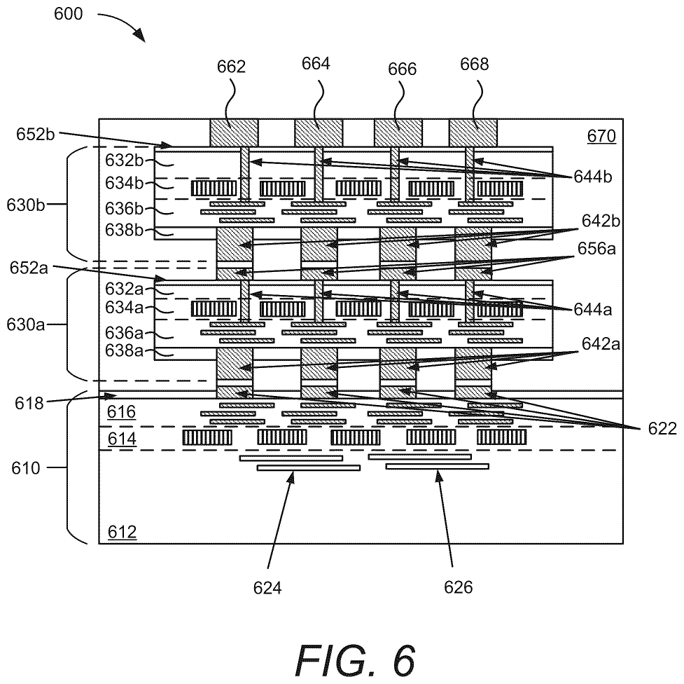

FIG. 6 is a cross-sectional view of a second example semiconductor device 600 that is configured with multiple stacked passive devices, according to aspects of the disclosure. In some aspects, the semiconductor device 600 may be referred to as a chip on wafer stacking semiconductor device. In some aspects, the semiconductor device 600 may be usable as the semiconductor device 106 in FIG. 1.

The semiconductor device 600 includes a first-tier passive device 610 and one or more second-tier passive devices 630a and 630b disposed over the first-tier passive device 610. While the example depicted in FIG. 6 shows two second-tier passive devices 630a and 630b over the first-tier passive device 610, in some aspects, there may be only one second-tier passive device or more than two second-tier passive devices stacked over the first-tier passive device 610.

The first-tier passive device 610 includes a substrate portion 612, a passive device portion 614, and a metallization portion 616 disposed in a stacked configuration. In some aspects, the passive device portion 614 may be disposed between the substrate portion 612 and the metallization portion 616. In this example, the passive device portion 614 of the first-tier passive device 610 is disposed over the substrate portion 612 of the first-tier passive device 610. The first-tier passive device 610 further includes a passivation layer 618 and electrical terminal structures 622 over the metallization portion 616. In some aspects, the substrate portion 612, the passive device portion 614, the metallization portion 616, the passivation layer 618, and the electrical terminal structures 622 may correspond to the substrate portion 310, the passive device portion 320, the metallization portion 330, the passivation layer 340, and the electrical terminal structures 352-358 may in FIG. 3, and detailed description thereof may be omitted.

In some aspects, while the deep trench capacitive structures are illustrated in this disclosure as the passive elements disposed in the passive device portion, the passive device portion may include a deep trench capacitor, an integrated stack capacitor, a metal-insulator-metal capacitor, a metal-oxide-metal capacitor, or a combination thereof. In some aspects, the passive device portion may include a capacitor, an inductor, a resistor, or a combination thereof.

In some aspects, the first-tier passive device 610 may further include one or more ESD protection circuits 624 and 626 disposed in the substrate portion 612 of the first-tier passive device 610 and electrically coupled to the passive device portion 614 of the first-tier passive device 610. In some aspects, the one or more ESD protection circuits 624 and 626 may include diodes (which are considered as passive components in this disclosure) configured to provide ESD protection functionality for the resulting passive component of the semiconductor device 600.

Moreover, each one of the one or more second-tier passive devices 630a and 630b may include a substrate portion 632a/632b, a passive device portion 634a/634b, and a metallization portion 616a/616b disposed in a stacked configuration, with the passive device portion 634a/634b being disposed between the substrate portion 632a/632b and the metallization portion 636a/636b. Each one of the one or more second-tier passive devices 630a and 630b may include a set of through substrate vias (TSVs) 644a/644b passing through the corresponding substrate portion 632a/632b and electrically coupled to the corresponding metallization portion 636a/636b. Also, each one of the one or more second-tier passive devices 630a and 630b include a passivation layer 638a/638b and electrical terminal structures 642a/642b adjacent the metallization portion 636a/636b. The second-tier passive device 630a may further include an etch stop layer 652a adjacent the substrate portion 632a, and electrical terminal structures 656a above the etch stop layer 652a. The second-tier passive device 630b may further include an etch stop layer 652b adjacent the substrate portion 632b.

In some aspects, the semiconductor device 600 includes an encapsulation structure 670 that is formed based on a molding material on the first-tier passive device 610 and surrounding the one or more second-tier passive devices 630a/630b. Also, the semiconductor device 600 may include electrical terminal structures 662, 664, 666, and 668 above the etch stop layer 652b and the encapsulation structure 670.

Various portions of the second-tier passive devices 630a and 630b are depicted as an unlimiting example. In some aspects, different portions within each one of the second-tier passive device 630a/630b may be individually configured to be stacked based on the same or a reverse order as illustrated in FIG. 6.

In some aspects, the semiconductor device 600 includes a passive component, which further includes the passive device portion 614 of the first-tier passive device 610 electrically coupled to one or more passive device portions 634a/634b of the one or more second-tier passive devices 630a/630b through the metallization portion 616 of the first-tier passive device 610, one or more sets of TSVs 644a/644b of the one or more second-tier passive devices 630a/630b, and one or more metallization portions 636a/636b of the one or more second-tier passive devices 630a/630b. In some aspects, at least two electrical terminal structures of the electrical terminal structures 662, 664, 666, and 668 disposed on an upper surface of an uppermost second-tier passive device (e.g., the second-tier passive device 630b in this example) of the one or more second-tier passive device 630a/630b may be configured as electrical terminals of the resulting passive component of the semiconductor device 600.

In some aspects, the electrical terminal structures 622 may be first conductive structures in the form of conductive pads, and the electrical terminal structures 642a may be second conductive structures in the form of conductive pillars bonded to the first conductive structures. In some aspects, the first conductive structures may be connected to the second conductive structures based on soldering bonding (e.g., by the soldering structures, not labeled and depicted as blocks respectively connecting the electrical terminal structures 622 and the electrical terminal structures 642a). In some aspects, the electrical terminal structures 656a may be third conductive structures in the form of conductive pads, and the electrical terminal structures 642b may be fourth conductive structures in the form of conductive pillars bonded to the third conductive structures. In some aspects, the third conductive structures may be connected to the fourth conductive structures based on soldering bonding (e.g., by the soldering structures, not labeled and depicted as blocks respectively connecting the electrical terminal structures 656a and the electrical terminal structures 642b).

In some aspects, the substrate portion 612 of the first-tier passive device 610 may not have been further trimmed and thus may maintain substantially the thickness of a wafer substrate for manufacturing the first-tier passive device 610. In some aspects, the substrate portion 632a/632a of the second-tier passive device 630a/630b may have been further trimmed and thus may have a thickness less than the thickness of a wafer substrate for manufacturing the second-tier passive device 630a/630b. As such, a thickness of the substrate portion 612 of the first-tier passive device 610 may be greater than a thickness of substrate portions 632a/632b of the one or more second-tier passive devices 630a/630b.

In some aspects, similar to the semiconductor device 400, a total thickness of the semiconductor device 600 may be adjusted, based on adjusting the number of second-tier passive devices and the thickness of the second-tier passive device(s), to match the thickness of the core for a particular packaging task. In some aspects, an overall thickness of the semiconductor device 600 may range from 1.2 mm to 1.8 mm. Moreover, similar to the semiconductor device 400, the resulting passive component of the semiconductor device 600 may have an electrical characteristic based on a combined effect of at least the passive device portions 614, 634a, and/or 634b. As such, a greater capacitance or inductance may be implemented within the same footprint as the semiconductor device 300 based on stacking multiple passive devices.

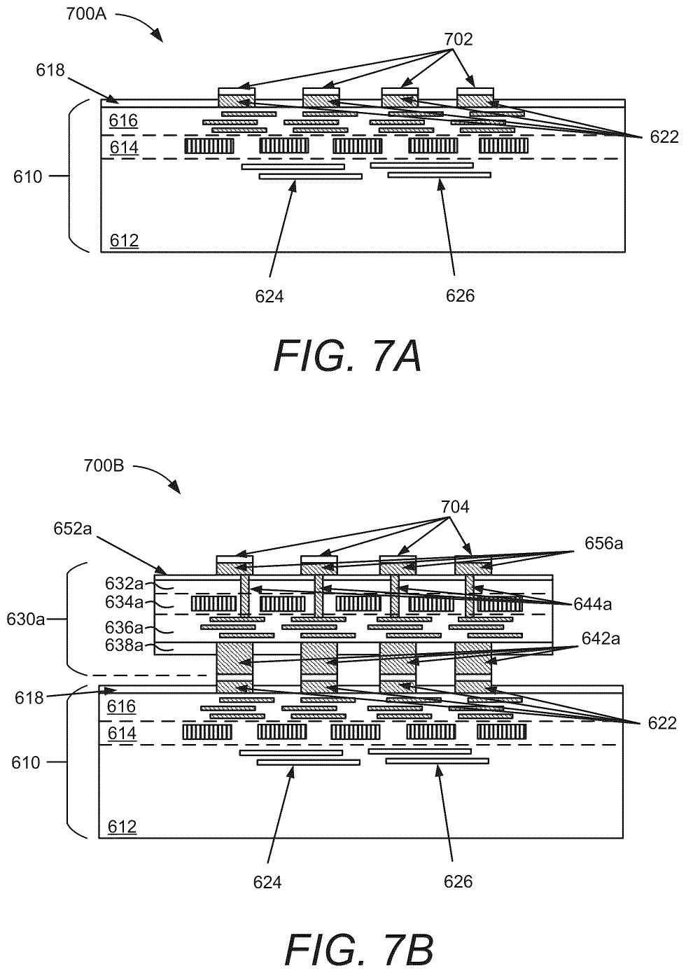

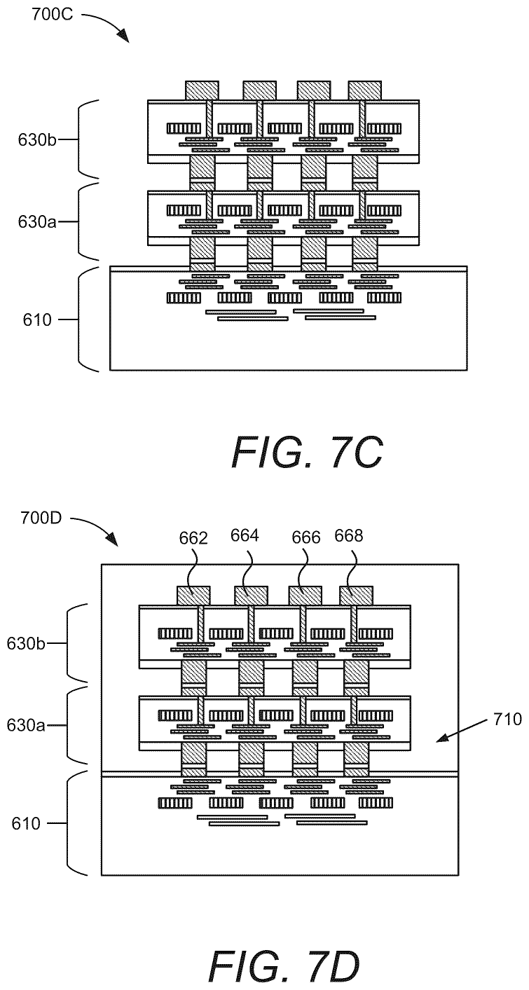

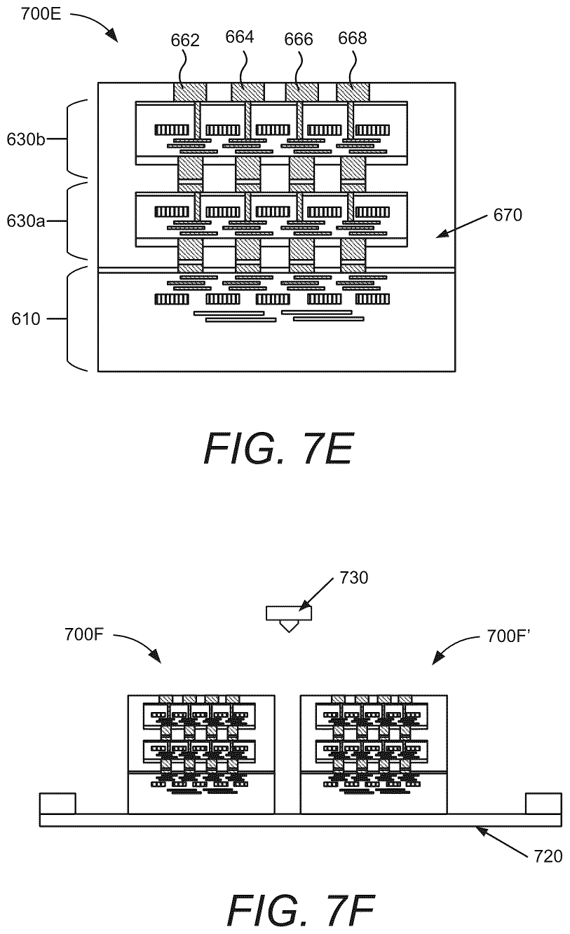

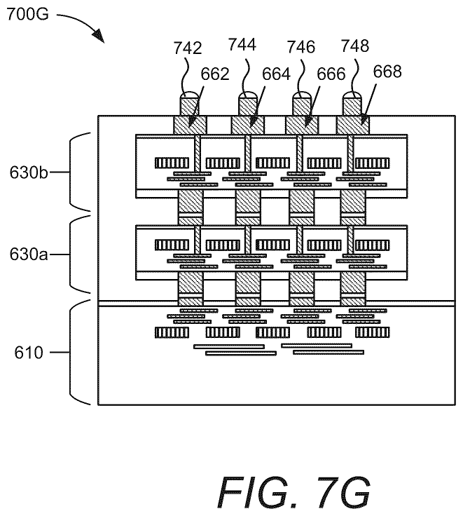

FIGS. 7A-7F illustrate structures at various stages of manufacturing a semiconductor device 600 of FIG. 6, according to aspects of the disclosure. The elements illustrated in FIGS. 7A-7F that are the same or similar to those of the semiconductor device 600 in FIG. 6 are given the same reference numbers, and the detailed description thereof may be omitted.

As shown in FIG. 7A, a structure 700A is provided. The structure 700A includes the first-tier passive device 610. In some aspects, the first-tier passive device 610 includes a substrate portion 612, a passive device portion 614, and a metallization portion 616 disposed in a stacked configuration. The first-tier passive device 610 further includes a passivation layer 618 and electrical terminal structures 622 over the metallization portion 616. In some aspects, the first-tier passive device 610 may further include one or more ESD protection circuits 624 and 626 disposed in the substrate portion 612 of the first-tier passive device 610 and electrically coupled to the passive device portion 614 of the first-tier passive device 610. In some aspects, the structure 700A further includes soldering structures 702 formed on the electrical terminal structures 622.

In some aspects, the electrical terminal structures 622 may be conductive pads and may include copper. In some aspects, after forming the electrical terminal structures 622 on the metallization portion 616, the passivation layer 618 may be formed by depositing a passivation material (e.g., an oxide material or a nitride material), and the upper surface of the first-tier passive device 610 may be prepared based on a chemical-mechanical polishing (CMP) process followed by a surface cleaning process (e.g., a surface plasma cleaning process). Afterwards, a soldering material may be deposited on the electrical terminal structures 622 to become the soldering structures 702.

As shown in FIG. 7B, a structure 700B is formed based on the structure 700A by attaching a second-tier passive device 630a to the first-tier passive device 610. The second-tier passive device 630a may be a die that has been manufactured and prepared for being stacked according to the present disclosure. In some aspects, the electrical terminal structures 622 and the electrical terminal structures 642a may be bonded based on soldering bonding by the soldering structures 702. In some aspects, if the second-tier passive device 630a is not the uppermost second-tier passive device, the electrical terminal structures 656a may have soldering structures 704 deposited thereon.

As shown in FIG. 7C, a structure 700C is formed based on the structure 700B by stacking all other second-tier passive device (e.g., second-tier passive device 630b) on the second-tier passive device 630a, based on the operations similar to those illustrated with reference to FIG. 7B.

As shown in FIG. 7D, a structure 700D is formed based on the structure 700C by disposing a molding material 710 on the first-tier passive device 610 and surrounding the one or more second-tier passive devices 630a/630b. In some aspects, the molding material may include resin. In some aspects, the molding material may be deposited based on a molded underfill (MUF) process.

As shown in FIG. 7E, a structure 700E is formed based on the structure 700D by grinding down the molding material 710 to become the encapsulation structure 670 and to expose the electrical terminal structures 662, 664, 666, and 668. In some aspects, if the first-tier passive device 610 at FIG. 7A is a stand-alone die, the structure 700E may correspond to the semiconductor device 600.

As shown in FIG. 7F, if the first-tier passive device 610 at FIG. 7A is not a stand-alone die but a part of a bottom wafer, a wafer dicing process may be performed as shown in FIG. 7F, including mounting the bottom wafer on a dicing tape 720 and then cutting the bottom wafer to separate the structures 700F and 700F′ based on a dicing saw or a dicing laser 730. Each one of the structures 700F and 700F′ may correspond to the structure 700E.

As shown in FIG. 7G, a structure 700G may be formed based on the structure 700E or the semiconductor device 600, by forming bump structures 742, 744, 746, and 748 on the electrical terminal structures 662, 664, 666, and 668. In some aspects, the bump structures 742, 744, 746, and 748 may be copper pillar bumps, solder bumps, or solder balls. In some aspects, the structure 700G may be an optional variation of the structure 700E. In some aspects, if the resulting semiconductor device is to be used inside a substrate core area, larger copper pads (e.g., the electrical terminal structures 662, 664, 666, and 668) may be used for substrate routing and connections, and the bump structures 742, 744, 746, and 748 as shown in FIG. 7G may not be needed.

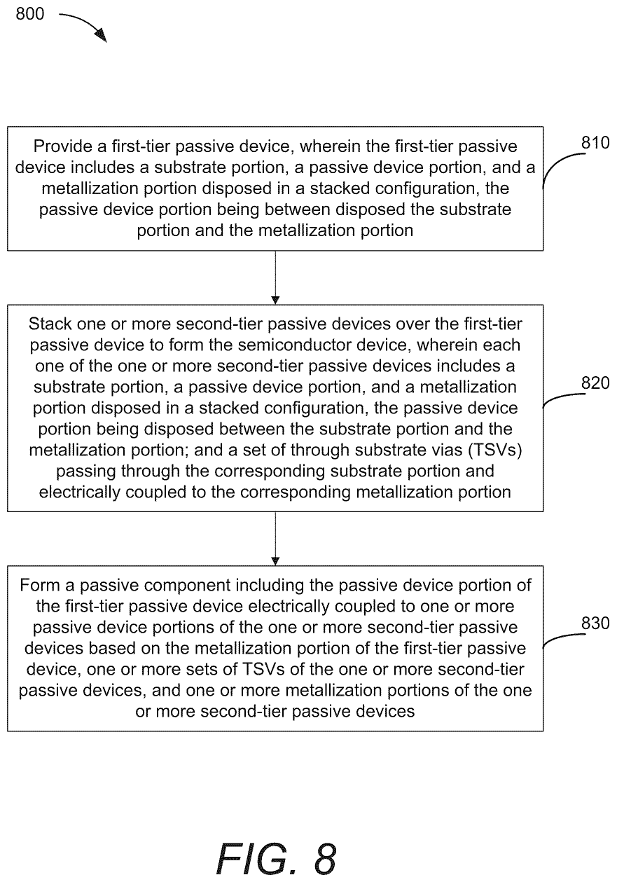

FIG. 8 illustrates a method 800 for manufacturing a semiconductor device (such as the semiconductor device 400 and 600), according to aspects of the disclosure.

At operation 810, a first-tier passive device (e.g., the first-tier passive device 410 or 610) is provided. In some aspects, the first-tier passive device may include a substrate portion (e.g., the substrate portion 412 or 612), a passive device portion (e.g., the passive device portion 414 or 614), and a metallization portion (e.g., the metallization portion 416 or 616) disposed in a stacked configuration. In some aspects, the passive device portion may be between disposed the substrate portion and the metallization portion.

At operation 820, one or more second-tier passive devices (e.g., the second-tier passive devices 430a/430b or 630a/630b) may be stacked over the first-tier passive device (e.g., the first-tier passive device 410 or 610) to form the semiconductor device (e.g., the semiconductor device 400 or 600). In some aspects, each one of the one or more second-tier passive devices may include a substrate portion (e.g., the substrate portion 432a/432b or 632a/632b), a passive device portion (e.g., the passive device portion 434a/434b or 634a/634b), and a metallization portion (e.g., the passive device portion 436a/436b or 636a/636b) disposed in a stacked configuration, and the passive device portion may be disposed between the substrate portion and the metallization portion.

At operation 830, a passive component may be formed, where the passive component includes the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

In some aspects, operation 820 may include attaching a first second-tier passive device (e.g., the second-tier passive device 430a or 630a) of the one or more second-tier passive devices to an upper surface of the first-tier passive device (e.g., the first-tier passive device 410 or 610). In some aspects, the first-tier passive device may further include first conductive structures that are disposed on the upper surface of the first-tier passive device, the first second-tier passive device may include second conductive structures, and the first conductive structures may be bonded to the second conductive structures.

In some aspects, operation 820 may include performing fusion bonding or hybrid bonding to connect the first conductive structures to the second conductive structures. In some aspects, operation 820 may include forming soldering structures that connect the first conductive structures to the second conductive structures.

In some aspects, operation 820 may include recessing a portion of the substrate portion of the first second-tier passive device, where the substrate portion of the first second-tier passive device may be disposed over the passive device portion of the first second-tier passive device. In some aspects, operation 820 may include forming third conductive structures that are disposed on an upper surface of the first second-tier passive device and are connected to the set of TSVs of the first second-tier passive device.

In some aspects, the method 800 may further include forming an ESD protection circuit (e.g., the ESD protection circuits 424/426 or 624/626) in the substrate portion of the first-tier passive device and electrically coupled to the passive device portion of the first-tier passive device. In some aspects, the method 800 may further include forming at least two electrical terminal structures (e.g., electrical terminal structures 462, 464, 466, and 468, or 662, 664, 666, and 668) on an upper surface of an uppermost second-tier passive device (e.g., the second-tier passive device 430b or 630b) of the one or more second-tier passive devices, where the at least two electrical terminal structures may be configured as electrical terminals of the passive component.

In some aspects, the method 800 may further include disposing a molding material on the first-tier passive device and surrounding the one or more second-tier passive devices to form an encapsulation structure.

In some aspects, the method 800 may further include forming the passive device portion of the first-tier passive device and the one or more passive device portions of the one or more second-tier passive devices that comprise a deep trench capacitor, an integrated stack capacitor, a metal-insulator-metal capacitor, a metal-oxide-metal capacitor, or a combination thereof.

A technical advantage of the method 800 is for formation of a semiconductor device with multiple stacked passive devices, such that the thickness of the semiconductor device may be adjustable to match the thickness of the core for a particular packaging task. The first-tier passive device of the semiconductor device may further include an ESD protection circuit. Also, an electrical characteristic of a resulting passive component may be improved or enhanced based on a combined effect of the stacked passive devices. For example, a resulting capacitor of a semiconductor device formed based on multiple stacked passive devices as illustrated above may have a capacitance based on combining the capacitance of all capacitive structures of the stacked passive devices, such that the resulting capacitor can have an increased capacitance value compared to a semiconductor device formed based on a single passive device and occupying the same footprint.

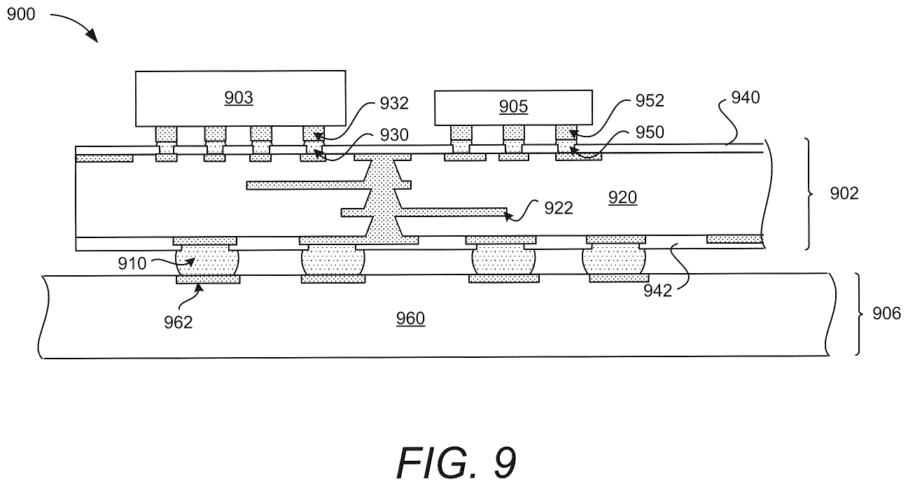

FIG. 9 illustrates a profile view of a package 900 that includes a surface mount substrate 902, an integrated device 903, and an integrated passive device 905 (e.g., with a packaging substrate and an embedded semiconductor device), according to aspects of the disclosure. The package 900 may be coupled to a printed circuit board (PCB) 906 through a plurality of solder interconnects 910. The PCB 906 may include at least one board dielectric layer 960 and a plurality of board interconnects 962.

The surface mount substrate 902 includes at least one dielectric layer 920 (e.g., substrate dielectric layer), a plurality of interconnects 922 (e.g., substrate interconnects), a solder resist layer 940 and a solder resist layer 942. The integrated device 903 may be coupled to the surface mount substrate 902 through a plurality of solder interconnects 930. The integrated device 903 may be coupled to the surface mount substrate 902 through a plurality of pillar interconnects 932 and the plurality of solder interconnects 930. The integrated passive device 905 may be coupled to the surface mount substrate 902 through a plurality of solder interconnects 950. The integrated passive device 905 may be coupled to the surface mount substrate 902 through a plurality of pillar interconnects 952 and the plurality of solder interconnects 950.

The package (e.g., 900) may be implemented in a radio frequency (RF) package. The RF package may be a radio frequency front end (RFFE) package. A package (e.g., 900) may be configured to provide Wireless Fidelity (WiFi) communication and/or cellular communication (e.g., 2G, 3G, 4G, 5G). The package (e.g., 900) may be configured to support Global System for Mobile (GSM) Communications, Universal Mobile Telecommunications System (UMTS), and/or Long-Term Evolution (LTE). The package (e.g., 900) may be configured to transmit and receive signals having different frequencies and/or communication protocols.

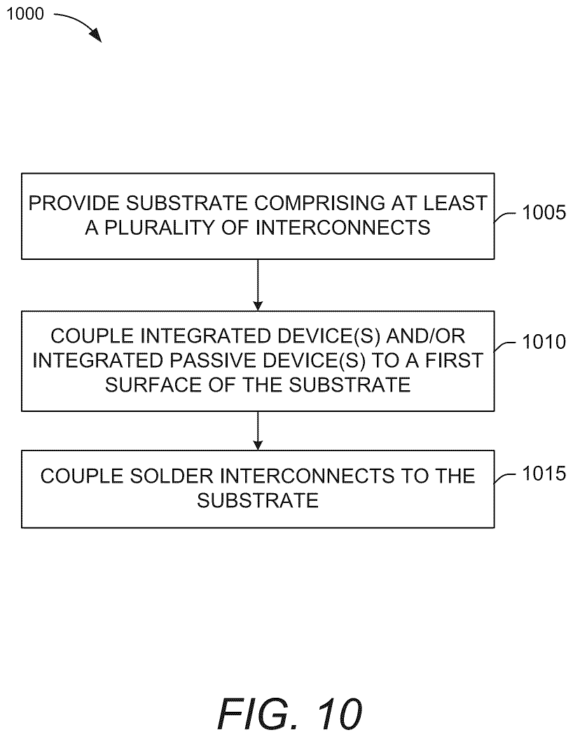

FIG. 10 illustrates an example method 1000 for providing or fabricating a package that includes an integrated device comprising an embedded semiconductor device, according to aspects of the disclosure. In some implementations, the method 1000 of FIG. 10 may be used to provide or fabricate the package 900 of FIG. 9 described in the disclosure. However, the method 1000 may be used to provide or fabricate any of the packages described in the disclosure.

It should be noted that the method of FIG. 10 may combine one or more processes in order to simplify and/or clarify the method for providing or fabricating a package that includes an integrated device comprising an integrated passive device. In some implementations, the order of the processes may be changed or modified.

The method provides (at 1005) a substrate (e.g., 902). The substrate 902 may be provided by a supplier or fabricated. The substrate 902 includes at least one dielectric layer 920, and a plurality of interconnects 922. The substrate 902 may include an embedded trace substrate (ETS). In some implementations, the at least one dielectric layer 920 may include prepreg layers.

The method couples (at 1010) at least one integrated device (e.g., 903) to the first surface of the substrate (e.g., 902). For example, the integrated device 903 may be coupled to the substrate 902 through the plurality of pillar interconnects 932 and the plurality of solder interconnects 930. The plurality of pillar interconnects 932 may be optional. The plurality of solder interconnects 930 are coupled to the plurality of interconnects 922. A solder reflow process may be used to couple the integrated device 903 to the plurality of interconnects through the plurality of solder interconnects 930.

The method also couples (at 1010) at least one integrated passive device (e.g., 905) to the first surface of the substrate (e.g., 902). For example, the integrated passive device 905 may be coupled to the substrate 902 through the plurality of pillar interconnects 952 and the plurality of solder interconnects 950. The plurality of pillar interconnects 952 may be optional. The plurality of solder interconnects 950 are coupled to the plurality of interconnects 922. A solder reflow process may be used to couple the integrated passive device 905 to the plurality of interconnects through the plurality of solder interconnects 950.

The method couples (at 1015) a plurality of solder interconnects (e.g., 910) to the second surface of the substrate (e.g., 902). A solder reflow process may be used to couple the plurality of solder interconnects 910 to the substrate.

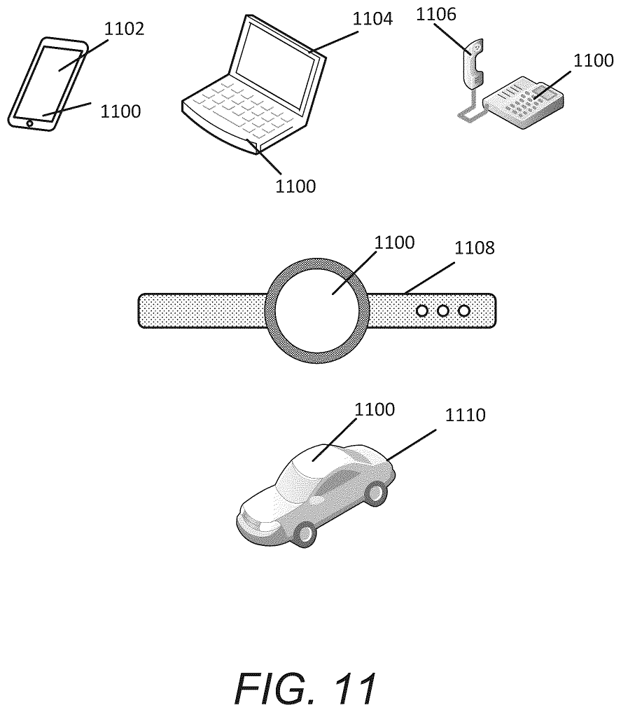

FIG. 11 illustrates various electronic devices that may be integrated with any of the aforementioned devices, integrated devices, integrated circuit (IC) packages, integrated circuit (IC) devices, semiconductor devices, integrated circuits, electronic components, dies, interposer packages, package-on-package (POP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A semiconductor device, comprising: a first-tier passive device including a substrate portion, a passive device portion, and a metallization portion disposed in a stacked configuration, the passive device portion being disposed between the substrate portion and the metallization portion; one or more second-tier passive devices disposed over the first-tier passive device, each one of the one or more second-tier passive devices including: a substrate portion, a passive device portion, and a metallization portion disposed in a stacked configuration, the passive device portion being disposed between the substrate portion and the metallization portion; and a set of through substrate vias (TSVs) passing through a corresponding substrate portion and electrically coupled to a corresponding metallization portion; and a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

Clause 2. The semiconductor device of clause 1, wherein the first-tier passive device further comprises: an electrostatic discharge (ESD) protection circuit disposed in the substrate portion of the first-tier passive device and electrically coupled to the passive device portion of the first-tier passive device.

Clause 3. The semiconductor device of any of clauses 1 to 2, wherein a thickness of the substrate portion of the first-tier passive device is greater than a thickness of substrate portions of the one or more second-tier passive devices.

Clause 4. The semiconductor device of any of clauses 1 to 3, wherein a thickness of the semiconductor device ranges from 1.2 mm to 1.8 mm.

Clause 5. The semiconductor device of any of clauses 1 to 4, further comprising: at least two electrical terminal structures disposed on an upper surface of an uppermost second-tier passive device of the one or more second-tier passive devices, the at least two electrical terminal structures being configured as electrical terminals of the passive component.

Clause 6. The semiconductor device of any of clauses 1 to 5, wherein: the passive device portion of the first-tier passive device is disposed over the substrate portion of the first-tier passive device, the first-tier passive device further comprises first conductive structures that are disposed on an upper surface of the first-tier passive device, the one or more second-tier passive devices include a first second-tier passive device, the first second-tier passive device includes second conductive structures, and the first conductive structures are bonded to the second conductive structures.

Clause 7. The semiconductor device of clause 6, wherein: the first conductive structures are connected to the second conductive structures based on fusion bonding or hybrid bonding.

Clause 8. The semiconductor device of clause 6, further comprising: first soldering structures that connect the first conductive structures to the second conductive structures.

Clause 9. The semiconductor device of any of clauses 6 to 8, wherein: the passive device portion of the first second-tier passive device is disposed over the substrate portion of the first second-tier passive device, and the second conductive structures are disposed on a lower surface of the first second-tier passive device and are connected to the set of TSVs of the first second-tier passive device.

Clause 10. The semiconductor device of any of clauses 6 to 8, wherein: the substrate portion of the first second-tier passive device is disposed over the passive device portion of the first second-tier passive device, and the second conductive structures are disposed on a lower surface of the first second-tier passive device and are adjacent the metallization portion of the first second-tier passive device.

Clause 11. The semiconductor device of any of clauses 1 to 10, further comprising: an encapsulation structure based on a molding material on the first-tier passive device and surrounding the one or more second-tier passive devices.

Clause 12. The semiconductor device of any of clauses 1 to 11, wherein: the passive device portion of the first-tier passive device and the one or more passive device portions of the one or more second-tier passive devices comprise a deep trench capacitor, an integrated stack capacitor, a metal-insulator-metal capacitor, a metal-oxide-metal capacitor, or a combination thereof.

Clause 13. A method of manufacturing semiconductor device, comprising: providing a first-tier passive device, wherein the first-tier passive device includes a substrate portion, a passive device portion, and a metallization portion disposed in a stacked configuration, the passive device portion being between disposed the substrate portion and the metallization portion; stacking one or more second-tier passive devices over the first-tier passive device to form the semiconductor device, wherein each one of the one or more second-tier passive devices includes: a substrate portion, a passive device portion, and a metallization portion disposed in a stacked configuration, the passive device portion being disposed between the substrate portion and the metallization portion; and a set of through substrate vias (TSVs) passing through a corresponding substrate portion and electrically coupled to a corresponding metallization portion; and forming a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

Clause 14. The method of clause 13, further comprising: forming an electrostatic discharge (ESD) protection circuit in the substrate portion of the first-tier passive device and electrically coupled to the passive device portion of the first-tier passive device.

Clause 15. The method of any of clauses 13 to 14, further comprising: forming at least two electrical terminal structures on an upper surface of an uppermost second-tier passive device of the one or more second-tier passive devices, the at least two electrical terminal structures being configured as electrical terminals of the passive component.

Clause 16. The method of any of clauses 13 to 15, wherein the stacking the one or more second-tier passive devices over the first-tier passive device comprises: attaching a first second-tier passive device of the one or more second-tier passive devices to an upper surface of the first-tier passive device, wherein: the first-tier passive device further comprises first conductive structures that are disposed on the upper surface of the first-tier passive device, the first second-tier passive device includes second conductive structures, and the first conductive structures are bonded to the second conductive structures.

Clause 17. The method of clause 16, wherein the attaching the first second-tier passive device of the one or more second-tier passive devices to the upper surface of the first-tier passive device comprises: performing fusion bonding or hybrid bonding to connect the first conductive structures to the second conductive structures.

Clause 18. The method of clause 16, wherein the attaching the first second-tier passive device of the one or more second-tier passive devices to the upper surface of the first-tier passive device comprises: forming first soldering structures that connect the first conductive structures to the second conductive structures.

Clause 19. The method of any of clauses 16 to 18, further comprising: recessing a portion of the substrate portion of the first second-tier passive device, wherein the substrate portion of the first second-tier passive device is disposed over the passive device portion of the first second-tier passive device; and forming third conductive structures that are disposed on an upper surface of the first second-tier passive device and are connected to the set of TSVs of the first second-tier passive device.

Clause 20. The method of any of clauses 13 to 19, further comprising: disposing a molding material on the first-tier passive device and surrounding the one or more second-tier passive devices to form an encapsulation structure.

Clause 21. The method of any of clauses 13 to 20, further comprising: forming the passive device portion of the first-tier passive device and the one or more passive device portions of the one or more second-tier passive devices that comprise a deep trench capacitor, an integrated stack capacitor, a metal-insulator-metal capacitor, a metal-oxide-metal capacitor, or a combination thereof.

Clause 22. An electronic device, comprising: an integrated circuit device including a semiconductor device, and the semiconductor device comprising: a first-tier passive device including a substrate portion, a passive device portion, and a metallization portion disposed in a stacked configuration, the passive device portion being disposed between the substrate portion and the metallization portion; one or more second-tier passive devices disposed over the first-tier passive device, each one of the one or more second-tier passive devices including: a substrate portion, a passive device portion, and a metallization portion disposed in a stacked configuration, the passive device portion being disposed between the substrate portion and the metallization portion; and a set of through substrate vias (TSVs) passing through a corresponding substrate portion and electrically coupled to a corresponding metallization portion; and a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

Clause 23. The electronic device of clause 22, wherein the first-tier passive device further comprises: an electrostatic discharge (ESD) protection circuit disposed in the substrate portion of the first-tier passive device and electrically coupled to the passive device portion of the first-tier passive device.

Clause 24. The electronic device of any of clauses 22 to 23, wherein a thickness of the substrate portion of the first-tier passive device is greater than a thickness of substrate portions of the one or more second-tier passive devices.

Clause 25. The electronic device of any of clauses 22 to 24, wherein a thickness of the semiconductor device ranges from 1.2 mm to 1.8 mm.

Clause 26. The electronic device of any of clauses 22 to 25, further comprising: at least two electrical terminal structures disposed on an upper surface of an uppermost second-tier passive device of the one or more second-tier passive devices, the at least two electrical terminal structures being configured as electrical terminals of the passive component.

Clause 27. The electronic device of any of clauses 22 to 26, wherein: the passive device portion of the first-tier passive device is disposed over the substrate portion of the first-tier passive device, the first-tier passive device further comprises first conductive structures that are disposed on an upper surface of the first-tier passive device, the one or more second-tier passive devices include a first second-tier passive device, the first second-tier passive device includes second conductive structures, and the first conductive structures are bonded to the second conductive structures.

Clause 28. The electronic device of clause 27, wherein: the first conductive structures are connected to the second conductive structures based on fusion bonding or hybrid bonding.

Clause 29. The electronic device of clause 27, wherein the semiconductor device further comprises: first soldering structures that connect the first conductive structures to the second conductive structures.

Clause 30. The electronic device of any of clauses 27 to 29, wherein: the passive device portion of the first second-tier passive device is disposed over the substrate portion of the first second-tier passive device, and the second conductive structures are disposed on a lower surface of the first second-tier passive device and are connected to the set of TSVs of the first second-tier passive device.

Clause 31. The electronic device of any of clauses 27 to 29, wherein: the substrate portion of the first second-tier passive device is disposed over the passive device portion of the first second-tier passive device, and the second conductive structures are disposed on a lower surface of the first second-tier passive device and are adjacent the metallization portion of the first second-tier passive device.

Clause 32. The electronic device of any of clauses 22 to 31, wherein the semiconductor device further comprises: an encapsulation structure based on a molding material on the first-tier passive device and surrounding the one or more second-tier passive devices.

Clause 33. The electronic device of any of clauses 22 to 32, wherein: the passive device portion of the first-tier passive device and the one or more passive device portions of the one or more second-tier passive devices comprise a deep trench capacitor, an integrated stack capacitor, a metal-insulator-metal capacitor, a metal-oxide-metal capacitor, or a combination thereof.

Clause 34. The electronic device of any of clauses 22 to 33, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more items. Also, as used herein, the terms “has,” “have,” “having,” and the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more items and may be used interchangeably with “at least one,” “one or more,” and the like. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. A semiconductor device, comprising:
a first-tier passive device including a substrate portion, a passive device portion, and a metallization portion disposed in a stacked configuration, the passive device portion being disposed between the substrate portion and the metallization portion;
one or more second-tier passive devices disposed over the first-tier passive device, each one of the one or more second-tier passive devices including:
a substrate portion, a passive device portion, and a metallization portion disposed in a stacked configuration, the passive device portion disposed between the substrate portion and the metallization portion; and
a set of through substrate vias (TSVs) passing through a corresponding substrate portion and electrically coupled to a corresponding metallization portion; and
a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

2. The semiconductor device of claim 1, wherein the first-tier passive device further comprises:
an electrostatic discharge (ESD) protection circuit disposed in the substrate portion of the first-tier passive device and electrically coupled to the passive device portion of the first-tier passive device.

3. The semiconductor device of claim 1, wherein a thickness of the substrate portion of the first-tier passive device is greater than a thickness of substrate portions of the one or more second-tier passive devices.

4. The semiconductor device of claim 1, wherein a thickness of the semiconductor device ranges from 1.2 mm to 1.8 mm.

5. The semiconductor device of claim 1, further comprising:
at least two electrical terminal structures disposed on an upper surface of an uppermost second-tier passive device of the one or more second-tier passive devices, the at least two electrical terminal structures being configured as electrical terminals of the passive component.

6. The semiconductor device of claim 1, wherein:
the passive device portion of the first-tier passive device is disposed over the substrate portion of the first-tier passive device,
the first-tier passive device further comprises first conductive structures that are disposed on an upper surface of the first-tier passive device,
the one or more second-tier passive devices include a first second-tier passive device,
the first second-tier passive device includes second conductive structures, and the first conductive structures are bonded to the second conductive structures.

7. The semiconductor device of claim 6, wherein:
the first conductive structures are connected to the second conductive structures based on fusion bonding or hybrid bonding.

8. The semiconductor device of claim 6, further comprising:
first soldering structures that connect the first conductive structures to the second conductive structures.

9. The semiconductor device of claim 6, wherein:
the passive device portion of the first second-tier passive device is disposed over the substrate portion of the first second-tier passive device, and
the second conductive structures are disposed on a lower surface of the first second-tier passive device and are connected to the set of TSVs of the first second-tier passive device.

10. The semiconductor device of claim 6, wherein:
the substrate portion of the first second-tier passive device is disposed over the passive device portion of the first second-tier passive device, and
the second conductive structures are disposed on a lower surface of the first second-tier passive device and are adjacent the metallization portion of the first second-tier passive device.

11. The semiconductor device of claim 1, further comprising:
an encapsulation structure based on a molding material on the first-tier passive device and surrounding the one or more second-tier passive devices.

12. The semiconductor device of claim 1, wherein:
the passive device portion of the first-tier passive device and the one or more passive device portions of the one or more second-tier passive devices comprise a deep trench capacitor, an integrated stack capacitor, a metal-insulator-metal capacitor, a metal-oxide-metal capacitor, or a combination thereof.

13. A method of manufacturing semiconductor device, comprising:
providing a first-tier passive device, wherein the first-tier passive device includes a substrate portion, a passive device portion, and a metallization portion disposed in a stacked configuration, the passive device portion being between disposed the substrate portion and the metallization portion;
stacking one or more second-tier passive devices over the first-tier passive device to form the semiconductor device, wherein each one of the one or more second-tier passive devices includes:
a substrate portion, a passive device portion, and a metallization portion disposed in a stacked configuration, the passive device portion being disposed between the substrate portion and the metallization portion; and
a set of through substrate vias (TSVs) passing through a corresponding substrate portion and electrically coupled to a corresponding metallization portion; and
forming a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

14. The method of claim 13, further comprising:
forming an electrostatic discharge (ESD) protection circuit in the substrate portion of the first-tier passive device and electrically coupled to the passive device portion of the first-tier passive device.

15. The method of claim 13, further comprising:
forming at least two electrical terminal structures on an upper surface of an uppermost second-tier passive device of the one or more second-tier passive devices, the at least two electrical terminal structures being configured as electrical terminals of the passive component.

16. The method of claim 13, wherein the stacking the one or more second-tier passive devices over the first-tier passive device comprises:
attaching a first second-tier passive device of the one or more second-tier passive devices to an upper surface of the first-tier passive device,
wherein:
the first-tier passive device further comprises first conductive structures that are disposed on the upper surface of the first-tier passive device,
the first second-tier passive device includes second conductive structures, and
the first conductive structures are bonded to the second conductive structures.

17. The method of claim 16, wherein the attaching the first second-tier passive device of the one or more second-tier passive devices to the upper surface of the first-tier passive device comprises:
performing fusion bonding or hybrid bonding to connect the first conductive structures to the second conductive structures.

18. The method of claim 16, wherein the attaching the first second-tier passive device of the one or more second-tier passive devices to the upper surface of the first-tier passive device comprises:
forming first soldering structures that connect the first conductive structures to the second conductive structures.

19. The method of claim 16, further comprising:
recessing a portion of the substrate portion of the first second-tier passive device, wherein the substrate portion of the first second-tier passive device is disposed over the passive device portion of the first second-tier passive device; and
forming third conductive structures that are disposed on an upper surface of the first second-tier passive device and are connected to the set of TSVs of the first second-tier passive device.

20. The method of claim 13, further comprising:
disposing a molding material on the first-tier passive device and surrounding the one or more second-tier passive devices to form an encapsulation structure.

21. The method of claim 13, further comprising:
forming the passive device portion of the first-tier passive device and the one or more passive device portions of the one or more second-tier passive devices that comprise a deep trench capacitor, an integrated stack capacitor, a metal-insulator-metal capacitor, a metal-oxide-metal capacitor, or a combination thereof.

22. An electronic device, comprising:
an integrated circuit device including a semiconductor device, and the semiconductor device comprising:
a first-tier passive device including a substrate portion, a passive device portion, and a metallization portion disposed in a stacked configuration, the passive device portion being disposed between the substrate portion and the metallization portion;
one or more second-tier passive devices disposed over the first-tier passive device, each one of the one or more second-tier passive devices including:
a substrate portion, a passive device portion, and a metallization portion disposed in a stacked configuration, the passive device portion being disposed between the substrate portion and the metallization portion; and
a set of through substrate vias (TSVs) passing through a corresponding substrate portion and electrically coupled to a corresponding metallization portion; and
a passive component including the passive device portion of the first-tier passive device electrically coupled to one or more passive device portions of the one or more second-tier passive devices through the metallization portion of the first-tier passive device, one or more sets of TSVs of the one or more second-tier passive devices, and one or more metallization portions of the one or more second-tier passive devices.

23. The electronic device of claim 22, wherein the first-tier passive device further comprises:
an electrostatic discharge (ESD) protection circuit disposed in the substrate portion of the first-tier passive device and electrically coupled to the passive device portion of the first-tier passive device.

24. The electronic device of claim 22, wherein a thickness of the substrate portion of the first-tier passive device is greater than a thickness of substrate portions of the one or more second-tier passive devices.

25. The electronic device of claim 22, wherein a thickness of the semiconductor device ranges from 1.2 mm to 1.8 mm.

26. The electronic device of claim 22, further comprising:
at least two electrical terminal structures disposed on an upper surface of an uppermost second-tier passive device of the one or more second-tier passive devices, the at least two electrical terminal structures being configured as electrical terminals of the passive component.

27. The electronic device of claim 22, wherein:
the passive device portion of the first-tier passive device is disposed over the substrate portion of the first-tier passive device,
the first-tier passive device further comprises first conductive structures that are disposed on an upper surface of the first-tier passive device,
the one or more second-tier passive devices include a first second-tier passive device,
the first second-tier passive device includes second conductive structures, and
the first conductive structures are bonded to the second conductive structures.

28. The electronic device of claim 27, wherein:
the first conductive structures are connected to the second conductive structures based on fusion bonding or hybrid bonding.

29. The electronic device of claim 27, wherein the semiconductor device further comprises:
first soldering structures that connect the first conductive structures to the second conductive structures.

30. The electronic device of claim 27, wherein:
the passive device portion of the first second-tier passive device is disposed over the substrate portion of the first second-tier passive device, and
the second conductive structures are disposed on a lower surface of the first second-tier passive device and are connected to the set of TSVs of the first second-tier passive device.

31. The electronic device of claim 27, wherein:
the substrate portion of the first second-tier passive device is disposed over the passive device portion of the first second-tier passive device, and
the second conductive structures are disposed on a lower surface of the first second-tier passive device and are adjacent the metallization portion of the first second-tier passive device.

32. The electronic device of claim 22, wherein the semiconductor device further comprises:
an encapsulation structure based on a molding material on the first-tier passive device and surrounding the one or more second-tier passive devices.

33. The electronic device of claim 22, wherein:
the passive device portion of the first-tier passive device and the one or more passive device portions of the one or more second-tier passive devices comprise a deep trench capacitor, an integrated stack capacitor, a metal-insulator-metal capacitor, a metal-oxide-metal capacitor, or a combination thereof.

34. The electronic device of claim 22, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
